(19) United States
(12) Patent Application Publication
(10) Pub. No.: US 2025/0033093 A1
(43) Pub. Date: Jan. 30, 2025

(54) DEVICES AND METHODS FOR CLEANING A FINISHED MONOCRYSTALLINE SQUARE ROD, AND GRINDERS

(71) Applicant: TCL ZHONGHUAN RENEWABLE ENERGY TECHNOLOGY CO., LTD., Tianjin (CN)

(72) Inventors: Yiqiang GONG, Tianjin (CN); Wenjun KUANG, Tianjin (CN); Furu WANG, Tianjin (CN); Hailong REN, Tianjin (CN); Zhihui LIANG, Tianjin (CN); Yanlong SHI, Tianjin (CN); Shun CHANG, Tianjin (CN); Shusheng YANG, Tianjin (CN); Yanhui ZHAO, Tianjin (CN); Yan SHI, Tianjin (CN)

(73) Assignee: TCL ZHONGHUAN RENEWABLE ENERGY TECHNOLOGY CO., LTD., Tianjin (CN)

(21) Appl. No.: 18/548,083

(22) PCT Filed: Jun. 26, 2023
(86) PCT No.: PCT/CN2023/102441

§ 371 Date: Aug. 26, 2023

(30) Foreign Application Priority Data
Jun. 29, 2022 (CN) 202210748570.3

(51) Int. Cl. B08B 3/02; B08B 5/02; C30B 29/06; C30B 29/66; C30B 33/00; C30B 35/00

(52) U.S. Cl. CPC B08B 3/022; B08B 5/023; C30B 29/66; C30B 33/00; C30B 35/00; B08B 2203/02; C30B 29/06

(57) ABSTRACT

A device for cleaning a finished monocrystalline square rod may include a washer arranged on a side of the square rod for washing the square rod and a dryer arranged around the square rod for blow-drying the washed square rod.

### CROSS-REFERENCE TO RELATED APPLICATION

The present disclosure claims priority to and the benefit of Chinese Patent Application No. 202210748570.3, filed on Jun. 29, 2022, the disclosure of which is incorporated herein by reference in its entirety.

### TECHNICAL FIELD

The present disclosure relates to monocrystalline silicon rod processing, and in particular, to devices and methods for cleaning a finished monocrystalline square rod, and grinders.

### BACKGROUND

Generally, after a monocrystalline square rod is processed by a grinder, the monocrystalline square rod will be unloaded for wiping and cleaning manually, so as to remove water stains residual after the processing procedure. If the ground monocrystalline square rod stays in a water vapor-rich environment for a long time, anomalies such as watermarks are easy to occur.

### SUMMARY

In view of the above, an embodiment of the present disclosure provides a device for cleaning a finished monocrystalline square rod, which includes a washer and a dryer, wherein the washer is arranged above the top of a square rod for washing the square rod, and the dryer is arranged around both sides of the square rod for blow-drying the washed square rod.

The present disclosure further provides a method for cleaning a finished monocrystalline square rod, wherein the method is carried out by using a device for cleaning a finished monocrystalline square rod, the cleaning device includes a washer and a dryer, wherein the washer is arranged above the top of a square rod for washing the square rod, and the dryer is arranged around both sides of the square rod for blow-drying the washed square rod; and the method comprises steps of:
disposing the square rod on one side of cleaning device for the finished monocrystalline square rod, and rotating the square rod along an axial direction;
turning on the washer;
moving the square rod along the axial direction to pass by the washer, and washing the square rod by the washer;
turning off the washer, and turning on the dryer;
moving the square rod along the axial direction to pass by the dryer, and blow-drying the square rod by the dryer; and
carrying out unloading.

### BRIEF DESCRIPTION OF THE DRAWINGS

FIG. 1 is a schematic structural diagram of a device for cleaning a finished monocrystalline square rod according to an embodiment of the present disclosure.

FIG. 2 is a schematic structural diagram of a grinder in which a device for cleaning a finished monocrystalline square rod is arranged according to an embodiment of the present disclosure.

FIG. 3a is a schematic diagram of a first structure of a washer according to an embodiment of the present disclosure.

FIG. 3b is a schematic diagram of a second structure of a washer according to an embodiment of the present disclosure.

FIG. 3c is a schematic diagram of a third structure of a washer according to an embodiment of the present disclosure.

FIG. 3d is a schematic diagram of a fourth structure of a washer according to an embodiment of the present disclosure.

FIG. 4a is a schematic diagram of a first structure of a dryer according to an embodiment of the present disclosure.

FIG. 4b is a schematic diagram of a second structure of a dryer according to an embodiment of the present disclosure.

FIG. 4c is a schematic diagram of a third structure of a dryer according to an embodiment of the present disclosure.

FIG. 4d is a schematic diagram of a fourth structure of a dryer according to an embodiment of the present disclosure.

FIG. 4e is a schematic diagram of a fifth structure of a dryer according to an embodiment of the present disclosure.

### DESCRIPTION OF REFERENCE NUMBERS

| | |
|---|---|
| 1: Washer | 2: Dryer |
| 3: Square rod | 10: Body |
| 11: Spraying member | 20: Blow-drying member |

### DETAILED DESCRIPTION

Hereinafter, the present disclosure will be further explained with reference to the accompanying drawings and some embodiments.

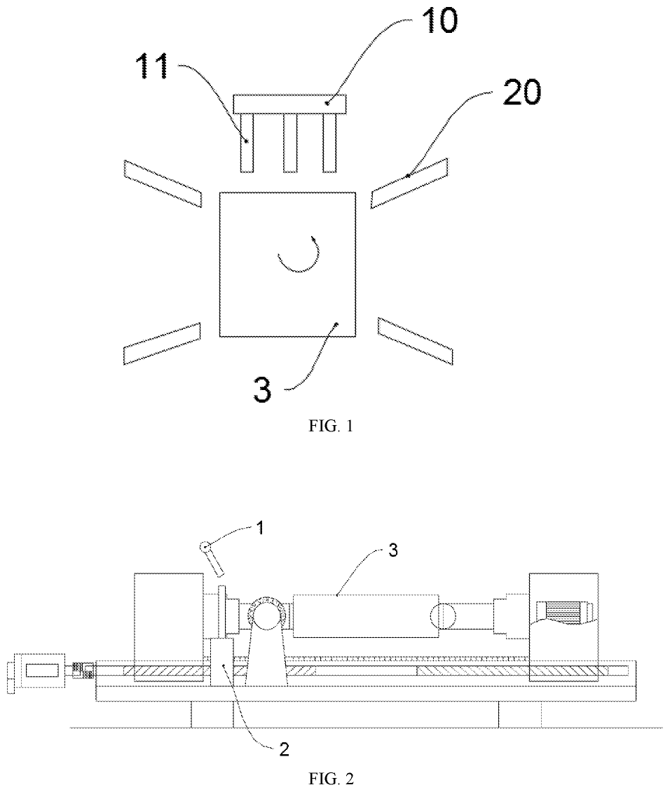

FIG. 1 is a schematic structural diagram of a device for cleaning a finished monocrystalline square rod according to an embodiment of the present disclosure. This embodiment relates to a device for cleaning a finished monocrystalline square rod, a grinder and a method for cleaning, which are used for washing and drying the ground finished monocrystalline square rod. After the square rod is squared and ground, cleaning is carried out instead of unloading. The square rod is washed with a washing liquid, and water vapor on the surface of the washed square rod is blown dry. During the washing and drying process, the square rod moves and rotates in the axial direction at the same time, so that the square rod after unloading is clean and dry, thus reducing manual operation, achieving a high automation degree, and avoiding abnormal surface quality of the square rod caused by untimely treatment of surface of the square rod.

A device for cleaning a finished monocrystalline square rod, as shown in FIGS. 1 and 2, comprises a washer 1 and a dryer 2. The washer 1 is arranged on one side of a square rod 3 and is used for washing the square rod 3. The dryer 2 is arranged on a peripheral side of the square rod 3, and is used for blow-drying the washed square rod 3. The device for cleaning a finished monocrystalline square rod is arranged inside a grinder. After the square rod is squared and ground in the grinder, the square rod is directly cleaned and blow-dried without unloading, and then unloading is carried out, so that the square rod 3 after unloading is clean and dry. Washing and blow-drying operations can be carried out inside the grinder, so that manual operation can be reduced, thus avoiding abnormal surface quality of the square rod caused by untimely treatment of surface of the square rod, and achieving a high automation degree.

When cleaning is performed on the ground square rod 3, firstly, the washer 1 washes the square rod 3 to wash off dirts on the surface of the square rod 3 and remove residual sludge during the processing procedure. After washing, the dryer 2 blow-dries the square rod 3, and blow-dries water vapor on the square rod 3, ensuring that the square rod 3 is clean, and avoiding anomalies such as watermarks on the surface of the monocrystalline square rod.

When the washer 1 washes the square rod 3, it uses a washing liquid, for example, water.

The position of the square rod 3 after grinding is taken as a reference direction, the washer 1 is arranged above the square rod 3 and is installed inside the grinder, and the washer does not interfere with the operation and installation of the grinding wheel in the grinder, its installation position is arranged according to actual installation requirements. The above washer 1 comprises a body 10 and a spraying member 11 communicating with the body 1. The number of the spraying members 11 is at least one, and the spraying member 11 has a spraying direction intersecting an axis of the square rod 3, so that washing liquid sprayed from the spraying member 11 is sprayed onto the square rod 3 to clean the square rod 3. The body 10 is connected with a power device outside the grinder, and the power device is connected with an external washing liquid storage device. Under the action of the power device, washing liquid in the washing liquid storage device enters inside of the body 10, flows inside of the body 10, and is sprayed from each spraying member 11. The body 10 has a tubular construction with a certain length, which is convenient for the flow of the washing liquid, and meanwhile, facilitates the installation of each of the spraying members 11. The length of the body 10 is selected according to the number of the spraying members 11 and the diameter of the square rod, which is not specifically limited herein. The cross-sectional shape of the body 10 may be rectangle, square, circle, ellipse, polygon, or the like, and may be selected according to actual requirements, which is not specifically limited herein. In this embodiment, the cross-sectional shape of the body 10 is, for example, a circle.

There may be at least one body 10 or a plurality of bodies 10. The number and setting mode of the bodies 10 can be selected and arranged according to the setting mode of the plurality of spraying members 11, so that the washing liquid sprayed out from each of the spraying members 11 can be sprayed on the square rod 3 to clean the square rod 3.

An axis of the body 10 intersects with the axis of the square rod 3. The body 10 is arranged along a width direction of the square rod 3. At least one row of spraying members 11 is arranged on the body 10. When a plurality of rows of spraying members 11 are arranged on the body 10, the plurality of rows of spraying members 11 may be arranged in parallel or in a staggered manner, and may be selectively arranged according to actual requirements.

The number of the spraying members 11 is at least one. However, in order to quickly wash the square rod 3, there may be a plurality of the spraying members 11 disposing in sequence along the length direction of the body 10. When the square rod 3 is washed, a plurality of the spraying members 11 spray washing liquid onto the square rod 3 simultaneously, so that washing area is large, and the washing efficiency is high, and the sludge on the surface of the square rod 3 can be quickly washed.

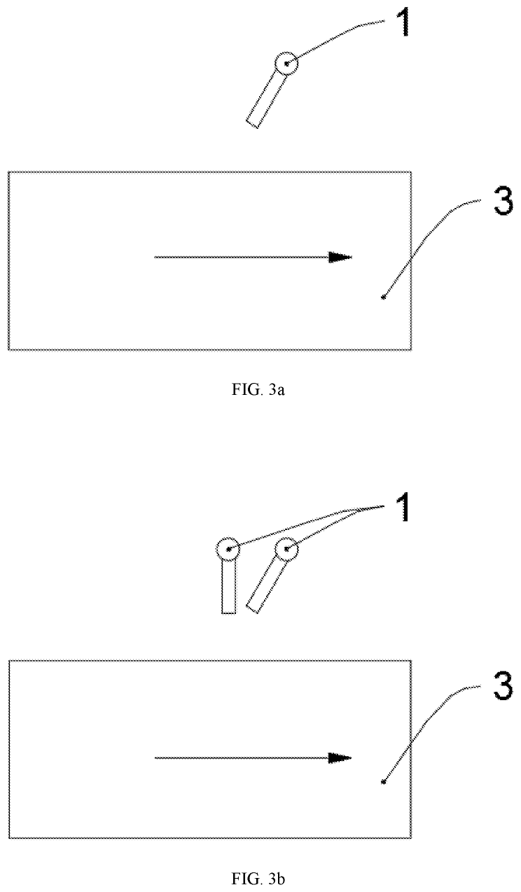

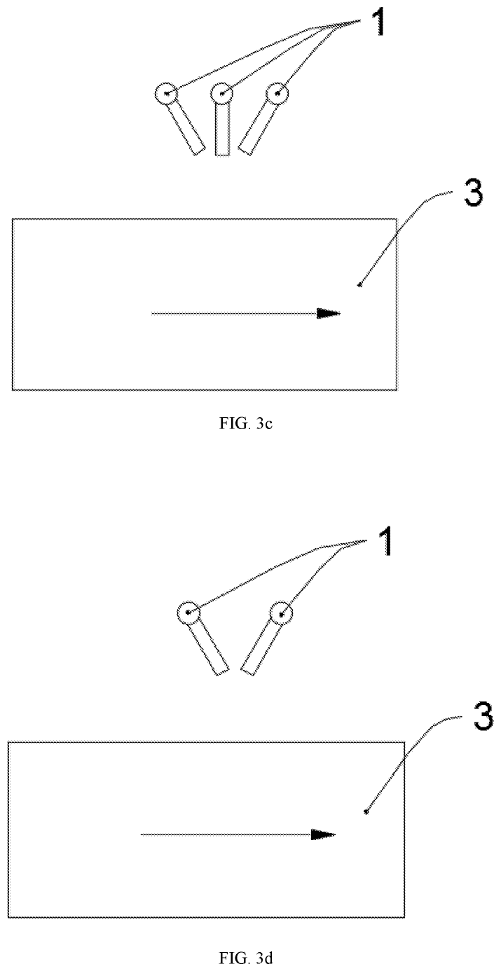

As shown in FIGS. 3a-3d, a plurality of spraying members 11 are arranged in parallel, and the spraying direction of each of the plurality of spraying members 11 is perpendicular to the axis of the square rod 3; or the plurality of spraying members 11 are arranged in parallel, and the spraying direction of each of the plurality of the spraying members 11 is arranged along an axial direction of the square rod 3 and is arranged inclined to the direction of the square rod 3. That is, the spraying direction of each of the plurality of spraying member 11 is intersects with the axis of the square rod 3. At this time, the plurality of spraying members 11 are arranged into a group, and spraying directions of each spraying member 11 are consistent. An angle between spraying direction of the spraying member 11 and advancing direction of the square rod 3 may be less than 90 degrees or greater than 90 degrees. At this time, the number of the body 10 is at least one. When there are a plurality of bodies 10, the plurality of bodies 10 are all arranged along the width direction of the square rod 3, the plurality of spraying members 11 on each of the plurality of bodies 10 are arranged in parallel, and the plurality of spraying members 11 are all arranged on one side of the body 10 facing the square rod 3, so that the washing liquid can be sprayed out from each spraying member 11 and obliquely sprayed onto the surface of the square rod 3, thus exerting a force on the surface of the square rod 3 to wash off the residual sludge on the surface of the square rod 3. Of course, the spraying members 11 of the plurality of bodies 10 may be arranged in the same way or different ways. For example, the plurality of bodies 10 are arranged in parallel.

Alternatively, the plurality of spraying members 11 are arranged into at least two groups, there are a plurality of the spraying members 11 in each group, and two adjacent spraying members 11 intersect with each other. For the two adjacent spraying members 11, the spraying direction of one spraying member 11 may be perpendicular to the surface of the square rod 3, and the spraying direction of the other spraying member 11 may be oblique to the surface of the square rod 3. Optionally, both the spraying directions of the two adjacent spraying members 11 may be oblique to the surface of the square rod 3, wherein the angle between the spraying direction of one spraying member 11 and the advancing direction of the square rod 3 is greater than 90 degrees, and the angle between the spraying direction of the other spraying member 11 and the advancing direction of the square rod 3 is less than 90 degrees.

Alternatively, the plurality of spraying members 11 are arranged into at least two groups, there are a plurality of the spraying members 11 disposing in parallel in each group, and two adjacent spraying members 11 intersect with each other. Specifically, the plurality of spraying members 11 are divided into two groups, wherein the spraying directions of the plurality of spraying members 11 in one group are all perpendicular to the axis of the square rod 3, the spraying directions of the plurality of spraying members 11 in the other group all intersect the axis of the square rod 3, and the spraying directions of the two groups of spraying members 11 are intersected at a place on the surface of the square rod 3, so that the two groups of spraying members 11 spray on the same place of the square rod 3. Optionally, the plurality of spraying members 11 are divided into three groups, wherein the spraying directions of the plurality of spraying members 11 in the first group are all perpendicular to the axis of the square rod 3, the spraying directions of the plurality of spraying members 11 in the second group all intersect with the axis of the square rod 3, and the spraying directions of the plurality of spraying members 11 in the third group all intersect the axis of the square rod 3. Further, the plurality of spraying members 11 in the second group and the plurality of spraying members 11 in the third group are respectively arranged on both sides of the plurality of spraying members 11 in the first group. The spraying directions of the spraying members 11 in the second group intersect with the spraying directions of the spraying members 11 in the third group. Alternatively, other setting modes can be selected according to actual requirements, and there are no specific liminations herein.

When the plurality of spraying members 11 are arranged into two groups, in one group of spraying members 11, the spraying direction of each spraying member 11 is perpendicular to the axis of the square rod 3; and in the other group of spraying members 11, the spraying direction of each spraying member 11 intersects with the axis of the square rod 3, and the angle between the spraying direction and the advancing direction of each spraying member 11 is less than 90 degrees. Alternatively, in one group of spraying members 11, the spraying direction of each spraying member 11 intersects with the axis of the square rod 3; and in the other group of spraying members 11, the spraying direction of each spraying member 11 intersects with the axis of the square rod 3, the spraying direction in one group intersects with the spraying direction in the other group, the angle between the spraying direction of each spraying member 11 in one group and the advancing direction of the square rod 3 is smaller than 90 degrees, and the angle between the spraying direction of each spraying member 11 in the other group and the advancing direction of the square rod 3 is greater than 90 degrees. Alternatively, in one group of spraying members 11, the spraying direction of each spraying member 11 is perpendicular to the axis of the square rod 3, and in the other group of spraying members 11, the spraying direction of each spraying member 11 intersects with the axis of the square rod 3, and the angle between the spraying direction of each spraying member 11 and the advancing direction of the direction is greater than 90 degrees. Each of the spraying members 11 in each group may be arranged on one body 10, or each of the spraying members 11 in each group may be arranged on a plurality of bodies 10 arranged in parallel, which can be arranged according to actual requirements.

When the plurality of spraying members 11 are arranged into three groups, in the first group of spraying members 11, the spraying direction of each spraying member 11 is perpendicular to the axis of the square rod 3; in the second group of spraying members 11, the spraying direction of each spraying member 11 intersects with the axis of the square rod 3, and the angle between the spraying direction of each spraying member 11 and the advancing direction of the square rod 3 is less than 90 degrees; in the third group of spraying members 11, the spraying direction of each spraying member 11 intersects with the axis of the square rod 3, and the angle between the spraying direction of each spraying member 11 and the advancing direction of the square rod 3 is greater than 90 degrees. Each of the spraying members 11 in each group may be arranged on one body 10, or each of the spraying members 11 in each group may be arranged on a plurality of bodies 10 arranged in parallel, which can be arranged according to actual requirements.

The spraying member 11 has a variable-diameter tube structure, and the diameter of the liquid outlet end of the spray member 11 is smaller than the diameter of the end connected with the body 10, so that the washing liquid can be sprayed out at a large speed, thus exerting a large force on the surface of the square rod 3 to wash off the sludge on the surface of the square rod 3. In this embodiment, the spraying member 11 is, for example, a high-pressure sprinkler, which is a commercially available product. It can be selected according to actual requirements, which is not specifically limited herein.

The axis of the body 10 intersects with the axis of the spraying member 11. Each of the plurality of the spraying members 11 is arranged on one side of the body 10 facing the square rod 3, and the liquid outlet faces the square rod 3, so that the washing liquid sprayed out from the spraying member 11 is sprayed onto the square rod 3.

The dryer 2 comprises a plurality of blow-drying members 20 and a blow-drying power device connected with each of the plurality of blow-drying members 20. The plurality of blow-drying members 20 are arranged along the peripheral side of the square rod 3, so as to blow-dry the water vapor on the surface of the square rod 3, ensuring that the surface of the square rod 3 is clean. Each of the plurality of blow-drying members 20 is connected with the blow-drying power device through a connecting pipe. Under the action of the blow-drying power device, the blow-drying member 20 injects high-pressure gas to blow-dry the residual water vapor on the surface of the square rod 3.

In this embodiment, the blow-drying power device is, for example, an air compressor.

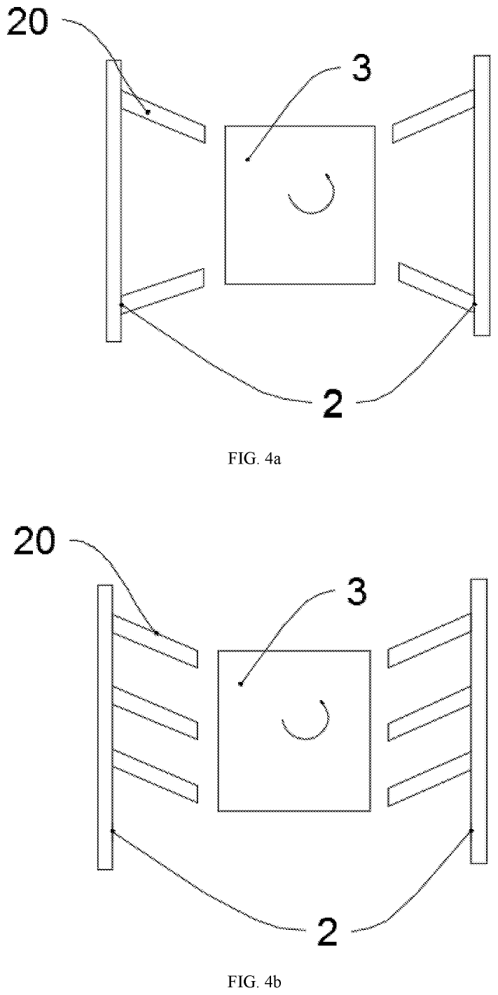

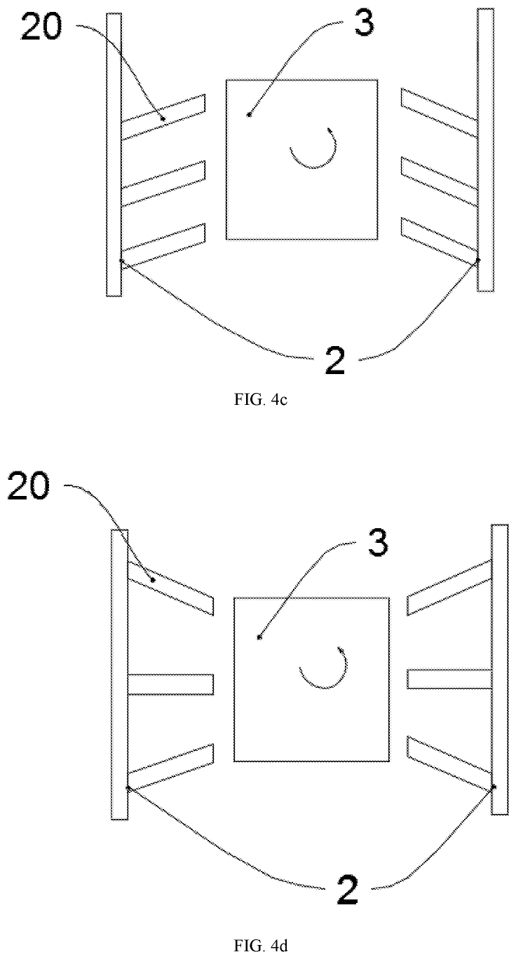

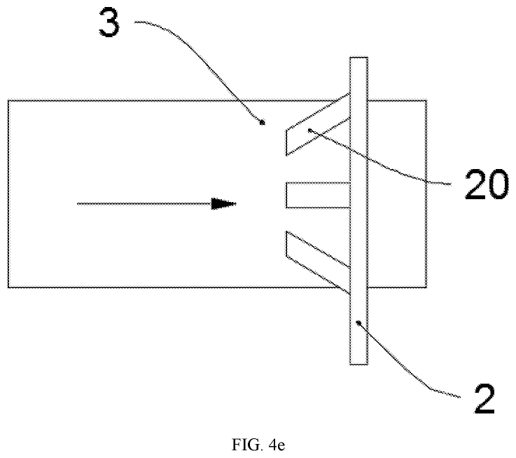

As shown in FIGS. 4a-4e, a plurality of blow-drying members 20 are arranged around peripheral side of the square rod 3, and the square rod 3 can rotate during the blow-drying process, so that the plurality of blow-drying members 20 are always capable of blowing air on the peripheral side surface of any position of the square rod 3. Meanwhile, the square rod 3 moves axially during the blow-drying process. With the movement of the square rod 3, the water vapor on any of the peripheral side surface of the square rod 3 can be blow-dried along the length direction of the square rod 3, and the water vapor on each surface of the square rod 3 can be gradually blow-dried.

In this embodiment, the plurality of blow-drying members 20 may be arranged into, for example, two groups, which are arranged on both sides of the square rod 3 along the length direction of the square rod 3, so that the plurality of blow-drying members 20 can be conveniently installed in the grinder.

The blowing direction of the blow-drying member 20 is arranged to intersect with the axis of the square rod 3, and a plurality of blow-drying members 20 on either side of the square rod 3 are all arranged in the same plane. Among the plurality of blow-drying members 20, the gas outlet of each blow-drying member 20 faces the square rod 3, and blows air on the surface of the square rod 3. The blowing directions of the plurality of blow-drying members 20 are arranged in parallel. The plurality of blow-drying members 20 may be perpendicular to the surface of the square rod 3, so that the gas blown out by the blow-drying member 20 is vertically blown onto the surface of the square rod. The plurality of blow-drying members 20 may also be arranged obliquely along the vertical direction, so that the gas blown out by the blow-drying member 20 is obliquely blown up or down to the surface of the square rod along the vertical direction. Alternatively, the blowing directions of the plurality of blow-drying members 20 are intersected. In the vertical direction, the blowing direction of some blow-drying members 20 is arranged obliquely upward, the blowing direction of some blow-drying members 20 is arranged obliquely downward, and the blowing direction of some blow-drying members 20 is perpendicular to the surface of the square rod 3, thereby blow-drying the surface of the opposite rod 3 from multiple directions.

In the above-mentioned several setting modes, each blow-drying member 20 is arranged along the radial direction of the square rod 3, and the plane where the plurality of blow-drying members 20 on both sides of the square rod 3 is arranged parallel to the end surface of the square rod 3. Alternatively, each blow-drying member 20 is arranged along the radial direction of the square rod 3, and is arranged inclined to the direction of the square rod 3, and the plane where the plurality of blow-drying members 20 on either side of the square rod 3 intersects with the end surface of the square rod 3. Other setting modes can be selected according to the actual requirements, and there is no specific liminations herein.

The plurality of blow-drying members 20 arranged on one side of the square rod 3 may be connected with the plurality of blow-drying members 20 arranged on the other side of the square rod 3 through one connecting pipe. Alternatively, the plurality of blow-drying members 20 arranged on both sides of the square rod 3 may be connected through one connecting pipe. For example, the plurality of blow-drying members 20 located on the same side of the square rod 3 are connected through a first connecting pipe, and the two first connecting pipes are respectively connected with the blow-drying power device. Under the action of the blow-drying power device, high-pressure gas enters the two first connecting pipes respectively, flows along the first connecting pipes, and is blown out from each blow-drying member 20. Alternatively, the plurality of blow-drying members 20 arranged on both sides of the square rod 3 are all connected through one connecting pipe, which is connected with the blow-drying power device. Under the action of the blow-drying power device, high-pressure gas flows along the connecting pipe and is blown out of each blow-drying member 20. Other setting modes can be selected according to the actual requirements, and there is no specific liminations herein.

In this embodiment, the blow-drying member 20 is, for example, a high-pressure blowing nozzle, which is a commercially available product, and can be selected according to actual requirements, there is no specific liminations herein.

A grinder, as shown in FIG. 2, comprises a device for cleaning a finished monocrystalline square rod as described above. The device for cleaning a finished monocrystalline square rod is arranged inside the grinder, and is installed on one side of a square rod. In the process of washing and blow-drying the square rod 3, the square rod 3 rotates and moves axially simultaneously, so that the whole square rod 3 can quickly washed and blow-dried.

The washer 1 and the dryer 2 may be fixedly installed inside the grinder by an installing member such as an installing bracket on one side of the grinding wheel. Alternatively, the washer 1 and the dryer 2 are movably installed inside the grinder by a sliding track and an installing bracket. When the square rod 3 is subjected to grinding, the washer 1 and the dryer 2 are far away from the square rod 3. After the square rod 3 is ground, and the square rod 3 needs to be washed and dried, the washer 1 and the dryer 2 approach the square rod 3, move to the side of the grinding wheel 3, and sequentially wash and blow-dry the square rod 3, followed by unloading, so as to realize unloading without stopping after grinding. In fact, unloading is carried out after cleaning and drying, thus reducing the time for stopping and unloading, reducing manual operation, realizing automation, and avoiding abnormal surface quality of the square rod caused by untimely treatment of surface of the square rod. Of course, the movement of the washer 1 and the dryer 2 can be realized by means of a screw drive structure, a rack and pinion drive structure, and the like, which can be selected according to actual requirements, and there are no specific liminations herein.

The device for cleaning a finished monocrystalline square rod is installed in a grinder and fixedly installed on one side of the grinding wheel. The square rod 3 after squaring is installed on a workbench in the grinder and is clamped by a top fixing clamper. The square rod 3 moves along the axial direction and rotates along its own axis under the action of the top fixing clamper. Both the washer 1 and the dryer 2 are installed inside the grinder, wherein the washer 1 is located above the square rod 3, the dryer 2 is located on both sides of the square rod 3, and the dryer 2 is located on one side of the grinding wheel. After grinding of the square rod 3 is completed, the washer 1 is operated, so that the washing liquid enters the body 10 under the action of the power device, flows along the body 10, and is sprayed from each spraying member 11. Meanwhile, the square rod 3 moves axially and rotates, and the square rod 3 passes through the washer 1 from one end to the other end sequentially to wash the whole square rod 3, so that the residual sludge left on the surface of the square rod 3 in the processing procedure can be washed off. After washing is completed, the dryer 2 is operated to blow high-pressure gas from each blow-drying member 20 under the action of the blow-drying power device. The square rod 3 passes through the dryer 2 from one end to the other end sequentially, and each blow-drying member 20 blows air onto the square rod 3 to dry the water vapor on the surface of the square rod 3. During the blow-drying process, the square rod 3 still keeps moving and rotating axially to ensure that monocrystalline square rod is clean. After blow-drying is completed, unloading is carried out.

A method for cleaning the finished monocrystalline square rod, comprising washing and drying a ground square rod 3 using a device for cleaning a finished monocrystalline square rod as described above. The method specifically comprises steps as follows:

Moving the square rod 3 along the axial direction at an axial moving speed of 50 mm/min to 300 mm/min, and simultaneously rotating the square rod 3 along the axis of the square rod 3 at a rotating speed of 10 r/min to 50 r/min. The axial moving speed may be 50 mm/min, 100 mm/min, 150 mm/min, 200 mm/min, 250 mm/min, 300 mm/min, or any speed value between 50 mm/min to 300 mm/min, which can be selected according to actual requirements, and it is not specifically liminated herein. The rotating speed may be 10 r/min, 20 r/min, 30 r/min, 40 r/min, 50 r/min or any rotation speed value between 10 r/min to 50 r/min, which can be selected according to actual requirements, and it is not specifically liminated herein.

Washing the washer 1 during the movement of the square rod 3. Specifically corresponding one end of the square rod 3 to the washer 1, or locating the square rod 3 on one side of the washer 1. Spraying washing liquid by using the washer 1, passing the square rod 3 through the washer 1 from one end to the other end sequentially, and simultaneously rotating the square rod 3, so that the washing liquid sprayed by each spraying member 11 can be directly sprayed on the square rod 3 to wash the sludge on each surface of the square rod 3. Moving the square rod 3 along the axial direction, so that the whole square rod 3 can be washed.

The washing time is 3 min to 20 min, which can be selected according to actual requirements, and it is not specifically liminated herein.

During the washing process, the square rod 3 can move axially in a single pass, and can also move axially back and forth, which can be selected according to actual requirements. The setting positions of the washer 1 and the dryer 2 can be selected according to the moving rule of the square rod 3.

After washing, carrying out blow-drying by using the dryer 2. During the blow-drying process, moving the square rod 3 axially, and simultaneously rotating the square rod 3. Locating the square rod 3 on one side of the dryer 2, or corresponding one end of the square rod 3 to the dryer 2. Blowing high-pressure gas through each blow-drying member 20, and blowing the high-pressure gas directly onto the surface of the square rod 3, so that the water vapor on the surface of the square rod 3 is blow-dried. Passing the square rod 3 through the dryer 2 from one end to the other end sequentially to blow-dry the water vapor on each surface of the square rod 3. Moving the square rod 3 along the axial direction, so that the whole square rod 3 can be blow-dried.

The blow-drying time is 3 min to 20 min, which can be selected according to actual requirements, and it is not specifically liminated herein.

During the blow-drying process, the square rod 3 can move axially in a single pass, and can also move axially back and forth, which can be selected according to actual requirements.

Carrying out unloading after the square rod 3 is blow-dried.

According to the above technical solutions, the device for cleaning a finished monocrystalline square rod is installed in a grinder and comprises a washer. The washer comprises a plurality of spraying members, so that high-pressure washing liquid can be sprayed. A liquid outlet of each spraying member faces the square rod, and the washing liquid is directly sprayed onto the square rod, so that sludge left on the ground square rod during the processing procedure can be washed, thus obtaining a clean monocrystalline square rod. The cleaning device further comprises a dryer, which comprises a plurality of blow-drying members capable of ejecting high-pressure gas. An air outlet of each blow-drying member faces a square rod, and the high-pressure gas is directly blown onto surface of the square rod, so that water vapor on the washed square rod is blown dry, and the surface of the square rod is clean. The washer and the dryer sequentially wash and blow-dry the ground square rod. During this process, the washer and the dryer keep stationary, and the square rod keeps moving axially and rotating axially during the washing and blow-drying process, so that sludge on the surface of the square rod can be washed off by the washer and blown dry by the dryer. After the grinding is completed, the washing and blow-drying operations are carried out directly, so that manual operation can be reduced, and abnormal surface quality of the square rod caused by untimely treatment of surface of the square rod can be avoided. After grinding, unloading is not carried out, but cleaning and blow drying are carried out, and then unloading is carried out, which improves automation degree of the device and reduce downtime for unloading.

Some embodiments of the present disclosure have been described in detail above, but should not be considered as limiting the scope of the present disclosure. All equivalents and modifications made in accordance with the present disclosure shall fall within the scope of the present disclosure.

What is claimed is:

1. A device for cleaning a finished monocrystalline square rod, comprising:
a washer arranged above a top of the square rod for washing the square rod; and
a dryer arranged around both sides of the square rod for blow-drying the washed square rod.

2. The device according to claim 1, wherein the washer comprises a body and one or more spraying members communicating with the body, and each spraying member of the spraying members has a spraying direction intersecting an axis of the square rod, to enable washing liquid sprayed from the spraying member to be sprayed onto the square rod to wash the square rod.

3. The device according to claim 2, wherein an axis of the body intersects each of the axis of the square rod and an axis of the spraying member.

4. The device according to claim 2, wherein the one or more spraying members comprise a plurality of spraying members arranged in sequence along a length direction of the body and arranged on a side of the body facing the square rod.

5. The device according to claim 4, wherein the plurality of spraying members are arranged in parallel, and the spraying direction of each of the plurality of spraying members is perpendicular to the axis of the square rod.

6. The device according to claim 4, wherein the plurality of spraying members are arranged in parallel, and the spraying direction of each of the plurality of spraying members is along an axial direction of the square rod and inclined to the square rod.

7. The device according to claim 4, wherein the plurality of spraying members are arranged in at least two groups each comprising plural spraying members two adjacent ones of which are arranged non-parallel.

8. The device according to claim 4, wherein the plurality of spraying members are arranged in at least two groups each comprising plural spraying members arranged in parallel, and two adjacent groups of the spraying members of the at least two groups are arranged non-parallel.

9. The device according to claim 1, wherein the dryer comprises a plurality of driers and a blow-drying power device connected with each of the plurality of driers, the plurality of driers are arranged around the square rod, and each of the plurality of the driers has a blowing direction intersecting an axis of the square rod to blow-dry the washed square rod.

10. The device according to claim 9, wherein the plurality of driers are arranged in two groups driers that are arranged respectively on both sides of the square rod, and plural driers in each of the two groups driers are arranged along a radial direction of the square rod.

11. The device according to claim 9, wherein driers the plurality of driers are arranged in two groups that are arranged respectively on both sides of the square rod, and plural driers in each of the two groups are arranged along an axial direction of the square rod and inclined to the square rod.

12. The device according to claim 3, wherein the one or more spraying members comprise a plurality of spraying members arranged in sequence along a length direction of the body and arranged on a side of the body facing the square rod.

13. The device according to claim 2, wherein the dryer comprises a plurality of driers and a blow-drying power device connected with each of the plurality of driers, the plurality of driers are arranged around the square rod, and each of the plurality of the driers has a blowing direction intersecting an axis of the square rod to blow-dry the washed square rod.

14. The device according to claim 3, wherein the dryer comprises a plurality of driers and a blow-drying power device connected with each of the plurality of driers, the plurality of driers are arranged around the square rod, and each of the plurality of the driers has a blowing direction intersecting an axis of the square rod to blow-dry the washed square rod.

15. The device according to claim 5, wherein the dryer comprises a plurality of driers and a blow-drying power device connected with each of the plurality of driers, the plurality of driers are arranged around the square rod, and each of the plurality of the driers has a blowing direction intersecting an axis of the square rod to blow-dry the washed square rod.

16. The device according to claim 6, wherein the dryer comprises a plurality of driers and a blow-drying power device connected with each of the plurality of driers, the plurality of driers are arranged around the square rod, and each of the plurality of the driers has a blowing direction intersecting an axis of the square rod to blow-dry the washed square rod.

17. The device according to claim 7, wherein the dryer comprises a plurality of driers and a blow-drying power device connected with each of the plurality of driers, the plurality of driers are arranged around the square rod, and each of the plurality of the driers has a blowing direction intersecting an axis of the square rod to blow-dry the washed square rod.

18. A grinder comprising the device according to claim 1 arranged inside the grinder.

19. A method for cleaning a finished monocrystalline square rod by the device of claim 1, comprising:
rotating the square rod close to the device along an axial direction of the square rod;
turning on the washer;
moving the square rod along the axial direction to pass by the washer, and washing the square rod by the washer;
turning off the washer, and turning on the dryer; and
moving the square rod along the axial direction to pass by the dryer, and blow-drying the square rod by the dryer.

20. The method according to claim 19, wherein the square rod is moved along the axial direction at a speed of 50 mm/min to 300 mm/min and is rotated at a speed of 10 r/min to 50 r/min, and the square rod is washed for a time of 3 min to 20 min and is blow-dried for a time of 3 min to 20 min.
